(19) United States
(12) Patent Application Publication
(10) Pub. No.: US 2007/0012401 A1
(43) Pub. Date: Jan. 18, 2007

(54) Plasma processing apparatus

(76) Inventors: Masaki Hirayama, Sendai-Shi (JP); Masashi Nakagawa, Tsukuba-Shi (JP); Tadahiro Ohmi, Sendai-Shi (JP)

Correspondence Address: YOUNG & THOMPSON, 745 SOUTH 23RD STREET, 2ND FLOOR, ARLINGTON, VA, 22202, US

(21) Appl. No.: 11/445,492

(22) Filed: Jun. 2, 2006

Related U.S. Application Data
(62) Division of application No. 09/546,892, filed on Apr. 10, 2000, now abandoned.

(30) Foreign Application Priority Data
Apr. 28, 1999 (JP) 11-122357

(51) Int. Cl. C23F 1/00; C23C 16/00

(52) U.S. Cl. 156/345.27; 118/725; 118/723 R; 156/345.28

(57) ABSTRACT

Apparatus for a plasma processing that can minimize losses of power dissipated, allow to shorten processing timescale and improve a yield. There are the insulating and heat insulating means (a plate for insulating and heat-insulating 7C) which is made of the material having low dielectric constant for insulating the high frequency and small thermal conductivity for heat insulating, a placing means (a stage 7A and a cooling plate 7B), for placing an object to be processed, provided with an electrode which is provided in a manner to overlap the insulating and heat insulating means, and to which a high frequency is supplied to generate bias, and a temperature adjusting means (pipings 5A, 5B, a cooling device 5C and a passage 701) which is provided on the placing means and controls temperature of this placing means.

### BACKGROUND OF THE INVENTION

1. Field of the Invention

This invention relates to an apparatus for a plasma processing which performs the plasma processing such as film deposition and dry etching for an object to be processed.

2. Background Art

The semiconductor manufacturing apparatus such as the apparatus for plasma processing performs a-processing, for example, for a wafer which is a silicon substrate as the object to be processed. Moreover, in recent years, it has been required to perform film deposition and dry etching having high performance at high speed for the apparatus for plasma processing. In concurrence with this, it has been required to suppress initial investments and running costs by size-reduction of an occupied floor area for installation of the apparatus for plasma processing.

An example of the apparatus for plasma processing has been shown in Japanese Laid-open Patent Publication No. Hei. 08-148478. Such apparatus for plasma processing has a stage provided in a chamber and performs the processing for the silicon substrate that is placed on this stage. Moreover, there are two types of a heating type and a cooling type in the apparatus for plasma processing.

A cooling stage has mainly been used in a plasma dry etching system of the apparatus of the cooling type. A cooling medium is supplied to the stage in order to increase an etch rate of a vertical direction as compared with that of a horizontal direction for the surface of the object to be processed, that is, in order to increase anisotropy of the etch rate. Heat of the object to be processed generated by irradiating with plasma is removed by cooling using this cooling medium. Furthermore, the cooling of the stage is required also for preventing from burning of an organic resist that will act as an etching mask. The cooling of the stage is similarly required also in a plasma film deposition system, when there is no heat resistance in the object to be processed or a thin film.

On the other hand, a heating stage has mainly been used in a plasma CVD system of the apparatus of the heating type. Moreover, since the temperature of the silicon substrate being the object to be processed becomes an important parameter for characteristic of a property of the film, the silicon substrate should be heated. Therefore, a temperature of the silicon substrate has been controlled by embedding a heater or the like in the stage.

In such apparatus for plasma processing, a processing rate is increased using high-density plasma in order to reduce a manufacturing cost. Moreover, the number of chips obtained from one piece of the substrate is increased by increasing a size of the silicon substrate in diameter from 200 [mm] to 300 [mm], thereby to attempt to increase productivity.

In the apparatus for plasma processing, it has been reported that power losses due to a RF current or a matching device which not flows into plasma, but flows into the chamber side via a parasitic capacitance, of RF (high-frequency) power introduced for processing the silicon substrate reach the extent of approximately 60 percent of the whole quantity. The parasitic capacitance has been become a problem as a large factor of power losses, when the power consumption of a RF bias in company with increasing in diameter is increased.

In the case of the stage to which DC current or the high frequency is supplied, in general, one which alumina ceramics and Kovar are thermal-sprayed in order to insulate DC voltage or the high frequency has been used. In this case, there are the problems on a stage structure with regard to the problem of the mentioned-above parasitic capacitance, and strength and heat insulation in company with increasing in diameter, although achieving also functions as vacuum sealing and heat insulation. Moreover, plasma seeds are leaner in the case of high-density microwave-excited plasma as compared with plasma excited by a prior parallel plate and an inductively coupled systems or the like. Therefore, since only the vicinity of a supplying point is biased when RF bias is supplied with the prior systems, it may be not biased uniformly over the surface. Therefore, deterioration of a yield or the like can be generated.

### SUMMARY OF THE INVENTION

The object of the invention is to provide an apparatus for plasma processing which can minimize the loss of the power being dissipated and allow to shorten processing timescale and improve the yield for solving such problems as described above.

This invention is an apparatus for plasma processing which allows to excite plasma in a container and an object to be processed located in said container is processed with said plasma and in which bias of the high frequency is applied to control processing with said plasma, said apparatus comprising:

insulating and heat insulating means provided in said container, and being made of material having low dielectric constant for insulating said high frequency and small thermal conductivity for heat insulating;

placing means provided in a manner to overlap said insulating and heat insulating means and provided with electrode to which said high frequency is supplied to generate bias, for placing the object to be processed; and

temperature adjusting means provided on said placing means for controlling a temperature of said placing means.

In the invention, said temperature adjusting means comprises a supplying section supplying a cooling medium for cooling and a passage being provided on said placing means, as well as flowing the cooling medium from said supplying section, and said placing means comprises a stage in which said electrode is provided and a cooling plate which is disposed between said stage and said insulating and heat insulating means, as well as in which said passage_is provided and which cools said stage by the cooling medium from said supplying section.

In the invention, said temperature adjusting means comprises a power source supplying power for heating and a heater which is provided in said placing means, as well as which is heated with the supplied power from said power source.

The invention is characterized by that material of said insulating and heat-insulating means is quartz.

The invention is characterized by that said electrode comprises electrode plates of two layers inside itself.

### BRIEF DESCRIPTION OF THE DRAWINGS

FIG. 1 is a configuration view showing an embodiment 1 according to the invention.

FIG. 2 is a configuration view showing an embodiment 2 according to the invention.

FIG. 3 is a sectional view showing a cross section of a heating stage in the embodiment 2.

FIG. 4 is a perspective view showing electrode being arranged on the heating stage in the embodiment 2.

FIG. 5 is a top plane view showing via-wiring used in heating stage in the embodiment 2.

### DESCRIPTION OF THE SYMBOLS

1 container body
2 microwave generating section
2A microwave generating device
2B waveguide
2C radial line slot antenna
3 gas supplying system
3A gas supplying device
3B supplying pipe
4 exhaust system
4A exhaust pipe
4B exhaust device
5 cooling system
5A, 5B piping
5C cooling device
6 high-frequency supplying section
6A high-frequency generating device
6B matching device
6C, 11A, 11B wiring
7 cooling stage section
7A stage
7B cooling plate
7C plate for insulating and heat-insulating
11 heating system
11C power source device
12 heating stage section
12A heating stage
12B plate for insulating and heat-insulating
12C supporting flange
71, 72 electrode plate
100 plasma
121 heater electrode
122, 123 electrode plate
124 via-wiring
701 passage

### DETAILED DESCRIPTION OF THE INVENTION

Hereinafter, the embodiments according to the invention will be described.

### Embodiment 1 of the Invention

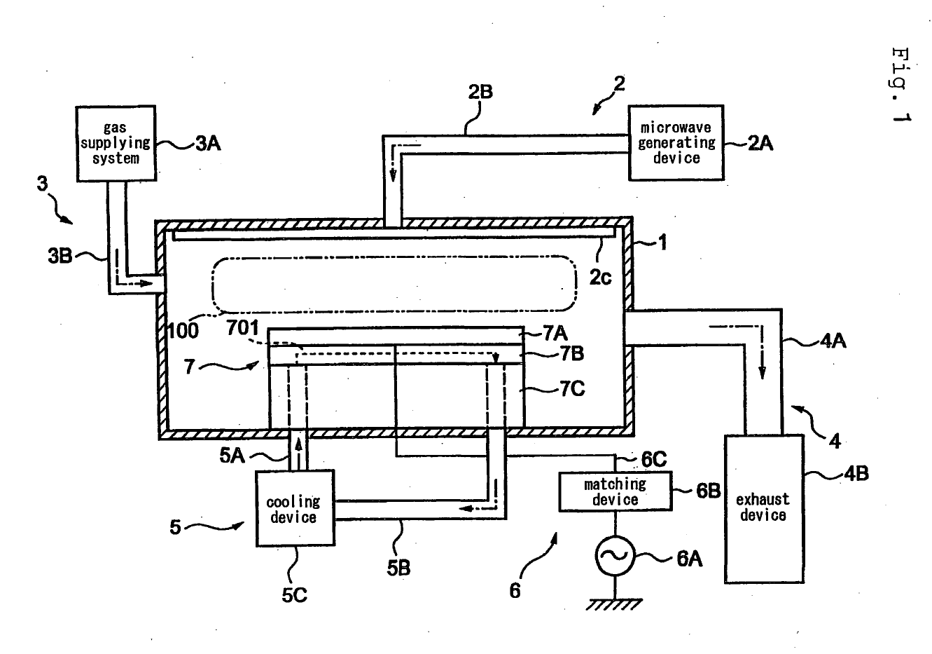

FIG. 1 is the configuration view showing the embodiment 1 according to the invention. In the embodiment 1, the invention is applied in a cooling stage-installed apparatus for plasma processing of the apparatus for plasma processing having the cooling stage. This cooling stage-installed apparatus for plasma processing dry-etches a silicon oxide film formed on the silicon substrate of 200 [mm] in diameter.

This cooling stage-installed apparatus for plasma processing is provided with a container body 1, a microwave generating section 2, a gas supplying system 3, an exhaust system 4, a cooling system 5 as a supplying section, a high-frequency supplying section 6 and a cooling stage section 7.

The container body 1 is a container that performs processing, which is a chamber or the like. When the silicon substrate is located in the container body 1, the container body 1 is closed. Namely, the container body 1 is an openable and closable sealed container.

The container body 1 is provided with microwave generating section 2. The microwave generating section 2 is provided with a microwave generating device 2A, a wave guide 2B, and a radial line slot antenna 2C. A microwave of 2.45 [GHz] oscillated and amplified in the microwave generating device 2A is supplied to the radial line slot antenna 2C through the waveguide 2B. The radial line slot antenna 2C is arranged on a ceiling in the container body 1. The microwave is radiated in a manner to spread toward the surface and uniformly by the radial line slot antenna 2C. Therefore, a plasma 100 is excited at the underside of the radial line slot antenna 2C.

The gas supplying system 3 is arranged on the container body 1. The gas supplying system 3 is provided with the gas supplying device 3A supplying raw material gases and a supplying pipe 3B flowing the raw material gases into the container body 1. The raw material gases required to excite a plasma 100 are applied into the container body 1 by means of the gas supplying system 3.

The surplus raw material gases and by-product gases are generated on the occasion of exciting the plasma 100. What exhausts these gases is an exhaust system 4 arranged on the container body 1. The exhaust system 4 is provided with an exhaust pipe 4A flowing the gases within the container body 1 and an exhaust device 4B exhausting the gases. The surplus raw material gases and by-product gases are exhausted by means of the exhaust system 4, and the pressure of the inside of the container body 1 is reduced.

A cooling system 5 and a high-frequency supplying section 6 are arranged on the container body 1. The cooling system 5 is provided with pipings 5A, 5B and a cooling device 5C. When recovering the cooling medium vaporized from the piping 5B, the cooling device 5C liquefies this cooling medium to send it to the piping 5A. The cooling medium is supplied to a cooling stage section 7. The high-frequency supplying section 6 is provided with a high-frequency generating device 6A and a matching device 6B. The high-frequency generating device 6A generates high frequency. The high frequency from the high-frequency generating device 6A is supplied to a cooling stage section 7 via a matching device 6B and a wiring 6C.

The container body 1 is provided with the cooling stage section 7. The cooling stage section 7 is provided with a stage 7A, a cooling plate 7B and a plate for insulating and heat-insulating 7C as the insulating and heat insulating means. In the embodiment 1, the stage 7A and the cooling plate 7B constitute the placing means. In the cooling stage section 7, the stage 7A, the cooling plate 7B and the plate for insulating and heat-insulating 7C are overlapped in turn each other.

The stage 7A is for locating the silicon substrate on. The stage 7A is made by material having volume resistivity of 1×10⁸ [Ω·cm] or more. Moreover, the high frequency from the high-frequency supplying section 6 is supplied to the stage 7A as bias. The stage 7A is provided with electrode of a two-layers structure in order for biasing the high frequency. This electrode of two-layers structure will be described in the following the embodiment 2 in detail. Bias of the high frequency is supplied to the stage 7A for the plasma 100 excited by microwave of 2.45 [GHz], thereby ion energy launched from the plasma 100 to the stage 7A adjusted.

The cooling plate 7B is arranged-on the lower of the stage 7A. The piping 5A, 5B of the cooling system 5 are installed on the cooling plate 7B, and the cooling medium from the cooling system 5 flows through a passages 701, whereby the cooling plate 7B can be cooled. As a result, the stage 7A also would be cooled. The cooling plate 7B is made by the material high in thermal conductivity for the purpose of cooling the stage 7A.

The plate for insulating and heat-insulating 7C is arranged between the lower of the cooling plate 7B and the bottom of the container body 1. The plate for insulating and heat-insulating 7C is made by the material low in dielectric constant for insulating the high frequency and small in thermal conductivity for heat insulating. There are quartz (silicon oxide), alumina ceramics or the like as such material. Moreover, the plate for insulating and heat-insulating 7C is made more thick as compared with that of the cooling plate 7B for increasing efficiency of heat insulation. Moreover, a flange for insulating and heat insulating may be used as a substitute of the plate for insulating and heat-insulating 7C. The high frequency supplied to the stage 7A is insulated and the cooling plate 7B is heat-insulated from the container body 1 side by means of the plate for insulating and heat-insulating 7C.

The power losses of RF due to the parasitic capacitance and the power losses of the cooling system 5 being a low temperature circulating chiller controlling the temperature of the silicon substrate can be reduced by the embodiment 1. Moreover, RF bias can be supplied to plasma large in seeds capacitance (lean in seeds) in the silicon substrate uniformly.

### Embodiment 2 of the Invention

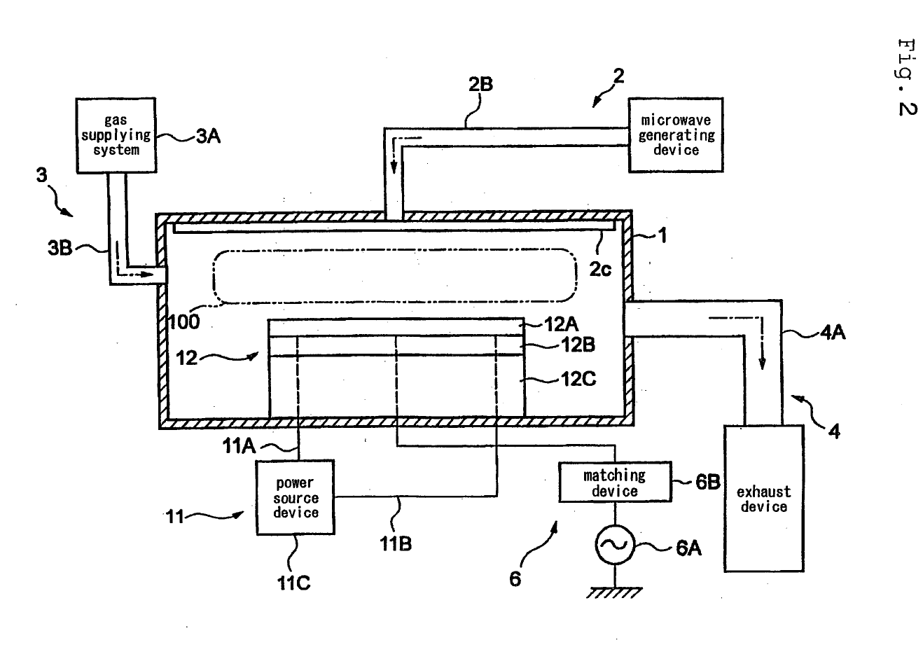

FIG. 2 is the configuration view showing the embodiment 2 according to the invention. In the embodiment 2, the invention is applied in a heating stage-installed apparatus for plasma processing of the apparatus for plasma processing having a heating stage. This heating stage-installed apparatus for plasma processing deposits a diamond film on the silicon substrate of 200 [mm] in diameter.

This heating stage-installed apparatus for plasma processing is provided with the container body 1, the microwave generating section 2, the gas supplying system 3, the exhaust system 4, the high-frequency supplying section 6, a heating system 11 and the heating stage section 12. Moreover, the same number is numbered to a member having the same function as FIG. 1 in FIG. 2, thereby the description to be omitted.

The heating system 11 is arranged as a substitute of the cooling system 5 of the container body 1 in the embodiment 1. The heating system 11 is provided with wiring 11A, 11B and a power source device 11C. The power source device 11C, supplies the power for heating to the heating system 11 through wiring 11A, 11B. DC or AC power source is used as the power source. The heating stage section 12 is arranged as a substitute of the cooling stage section 7 of the container body 1 in the embodiment 1. The heating stage section 12 is provided with the heating stage 12A, the plate for insulating and heat-insulating 12B and the supporting flange 12C as the placing means. The heating stage 12A, the plate for insulating and heat-insulating 12B and the supporting flange 12C are overlapped in turn each other in the heating stage section 12. In the embodiment 2, the heat-insulating 12B and the supporting flange 12C constitute the insulating and heat insulating means.

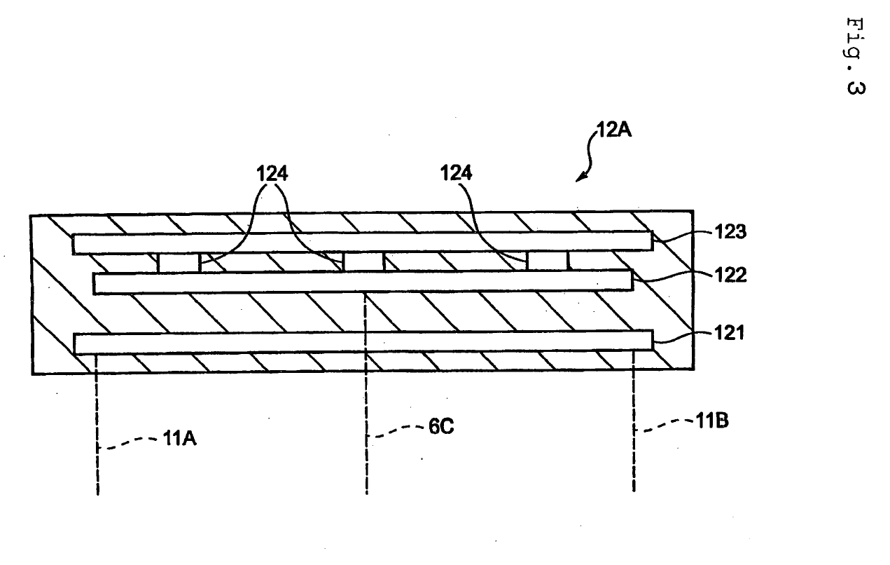

A heater electrode 121 to which the power from the heating system 11 is supplied are embedded in the inside of the heating stage 12A as shown in FIG. 3. The heater electrode 121 increase the temperature of the heating stage 12A by resistance heating with the power supplied. As a result, the silicon substrate located on the heating stage 12A is raised in temperature.

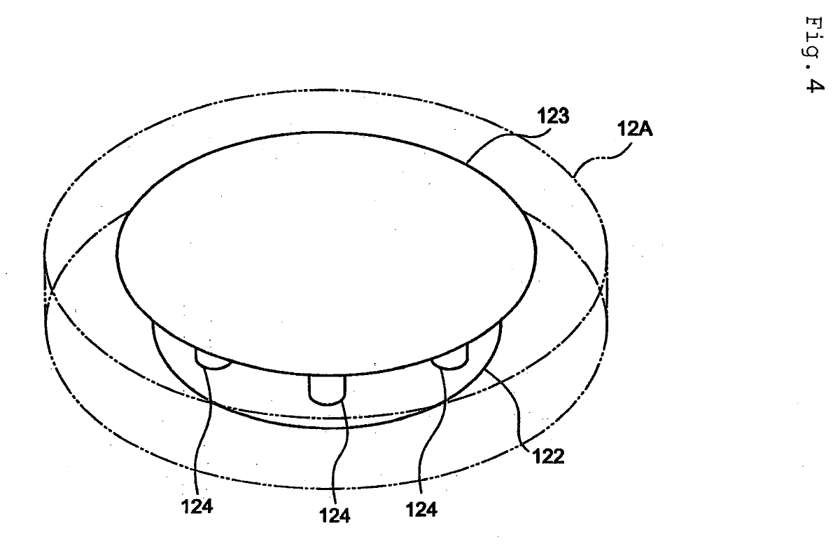

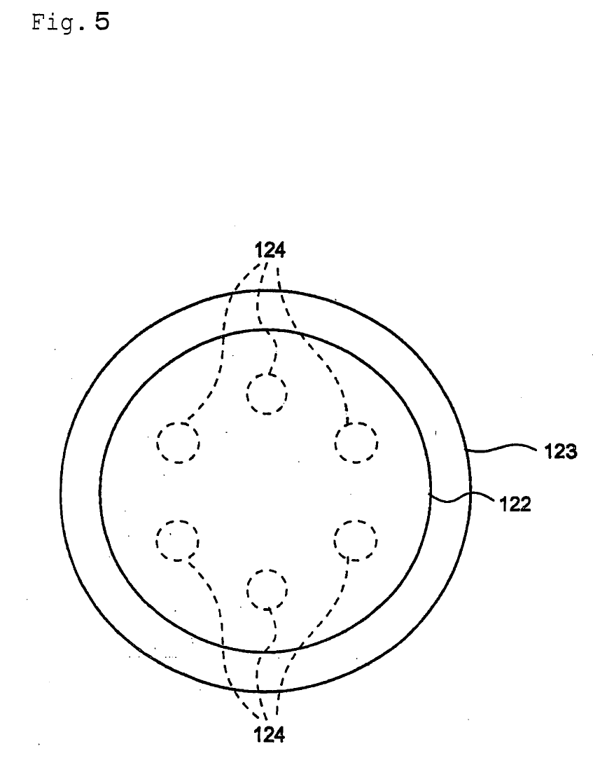

The electrode is provided with in the inside of the heating stage 12A for supplying bias of the high frequency. One example of this electrode is shown in FIG. 4. The electrode shown in FIG. 4 is the electrode of the two-layers structure, and is provided with a circular electrode plate 122 and a circular electrode plate 123 larger than the diameter of the electrode plate 122. The electrode plates 122 and 123 are formed in the form of meshes. Therefore, an effect that a stress of the electrode plates 122 and 123 due to the difference of thermal expansion coefficients between the heating stage 12A and the electrode plate 122 exerts on the heating stage 12A can be alleviated when the heating stage 12A is heated by the heater electrodes 121. The electrode plate 123 is electrically connected with the electrode plate 122 through a plurality of via-wiring 124. The via-wiring 124 is a cylindrical conductor. An aspect of wiring of the via-wiring 124 is shown in FIG. 5. The electrode plate 123 is arranged so as to distribute for the electrode plate 123 uniformly.

The high frequency supplied to the electrode plate 122 is supplied to the electrode plate 123 through a plurality of via-wiring 124. Therefore, the high frequency is transmitted to the electrode plate 123 being the high frequency electrode of the plasma 100 side, and flows into the plasma over the surface uniformly. The reason of this is as follows. Namely, heretofore, since the capacitance between the plasma and the electrode has been small, the resistance or inductance of the electrode does not exert an influence, so that the high frequency is made uniform at the electrode to flow in the plasma. However, the capacitance between the plasma and the electrode is large in the high density and low temperature plasma. Therefore, the high frequency flows to the plasma through the vicinity of the supplying point. Accordingly, when connecting the electrode plate 122 to the electrode plate 123 positioned at the plasma side with a plurality of via-wiring 124 and supplying the plasma through the via-wiring 124 providing a plurality of supplying points, the high frequency flows toward the plasma through the inside of the surface of the electrode plate 123 uniformly.

The plate for insulating and heat-insulating 12B is arranged on the lower of the heating stage 12A. The plate for insulating and heat-insulating 12B is made by material low in dielectric constant for insulating the high frequency and small in thermal conductivity for heat insulating in the same way as the plate for insulating and heat-insulating 7C in the embodiment 1. The high frequency supplied to the heating stage 12A is insulated and the heating stage 12A raised to high temperature is heat-insulated from the container body 1 side by means of the plate for insulating and heat-insulating 12B. Moreover, a flange for insulating and heat insulating may be used as a substitute of the plate for insulating and heat-insulating 12B.

The supporting flange 12C is for supporting the plate for insulating and heat-insulating 12B.

The power losses of RF due to the parasitic capacitance and the power losses of the heater electrode 121 in the heating stage 12A can be reduced by the embodiment 2. Moreover, RF bias can be supplied to the plasma large in seeds capacitance in the silicon substrate uniformly.

### EXAMPLE

Hereinafter, a specified example used the cooling stage section 7 of the cooling stage-installed apparatus for plasma processing of the embodiment 1 will be described. In this example, dry etching processing for the silicon substrate was performed under the condition that RF bias of 300 [W] was supplied to the stage 7A of the cooling stage section 7. The processing condition were as follows:
microwave power source output: 2.45 [GHz]/1500 [W]
stage high frequency power output: 13.56 [MHz]/300 [W]
processing gas: C₄F₈/CO/O₂/Ar=10/50/5/200 [sccm]
processing pressure: 40 [mTorr]
substrate: photoresist of 0.8 [μm] (hole pattern of φ0.15 [μm] formed)/silicon oxide film of 1.6 [μm]/silicon substrate of 0.75 [mm]
substrate stage temperature: controlled to 20 [° C.]
cooling medium: fluorine system inert liquid GARDEN HT-110 (made by AUGYMOND Inc.)

According to this processing condition, it could be as follows in the case of the prior stage structure: Namely, in the etch rate of the silicon oxide film, there were variations in the surface as was approximately 400 [nm]/[min] at the center, and 380 [nm]/[min] at the position of 90 [mm] from the center in the substrate of 8 inches.

However, it was obtained the result that both of the etching rate were 550 [n m]/[min] at the center, and at the position of 90 [mm] from the center under the same condition by using the apparatus according to the invention. The result of 550 [n m]/[min] is comparable to the etch rate at the center in the case to which RF bias of 500 [W] was supplied with the prior stage structure, and the variations in the surface has been eliminated. It has been verified from this result that RF powercan be applied to the plasma efficiently by adoption of the plate for insulating and heat-insulating 7C and the high frequency can be supplied over the surface uniformity by means of the electrode of the two-layers structure.

Moreover, the output result of the power source device 11C under the condition of holding the heating stage 12A at 200 [° C.] using the heating stage section 12 of the heating stage-installed apparatus for plasma processing in the embodiment 2 will be described. Power consumption of the heater under the condition of holding the stage of 8 inches at 200 [° C.] in the prior apparatus were the degree of approximate 40 [W]. However, it has been verified that approximate 20 [M] can be obtained by using the plate for insulating and heat-insulating 12B and heat insulating ability can be improved in the invention.

Although the embodiments 1 and 2 have been described above, the invention can not be limited thereto. For example, although bias of the high frequency is used in order to control the processing by the plasma in the embodiments 1 and 2, bias by DC voltage also may be used.

(Effects of The Invention)

As described above, according to the invention, the high frequency for bias can be prevented from flowing into the container side due to the parasitic capacitance by insulating, and chilled heat used in temperature adjustment can be prevented from dispersing by heat insulation, thereby to be able to minimize the losses of the power being dissipated and allow to shorten processing timescale and to improve the yield. As a result of this, the running costs for the apparatus can be suppressed inexpensively.

Moreover, the high frequency bias can be supplied to the plasma large in seeds capacitance over the surface uniformly by forming the embedded electrode into the two-layers structure in turn from the plasma side, thereby to be able to shorten over-etching timescale and to improve the yield.

What is claimed is:

1. An apparatus for plasma processing which allows excited plasma in a container and an object to be processed located in said container is processed with said plasma and in which bias of the high frequency is applied to control processing with said plasma, comprising:
insulating and heat insulating means provided in said container, and being made of material having low dielectric constant for insulating said high frequency and small thermal conductivity for heat insulating;
placing means provided in a manner to overlap said insulating and heat insulating means and provided with electrode to which said high frequency is supplied to generate bias, for placing the object to be processed; and
temperature adjusting means provided on said placing means for controlling a temperature of said placing means.

2. The apparatus for plasma processing according to claim 1, wherein said temperature adjusting means comprises a supplying section supplying a cooling medium for cooling and a passage provided on said placing means, for flowing the cooling medium from said supplying section, and said placing means comprising a stage in which said electrode is provided and a cooling plate which is disposed between said stage and said insulating and heat insulating means, as well as in which said passage is provided and which cools said stage by the cooling medium from said supplying section.

3. The apparatus for plasma processing according to claim 1, wherein said temperature adjusting means comprises a power source supplying power for heating and a heater provided in said placing means, and heated with the supplied power from said power source.

4. The apparatus for plasma processing according to claim 1, wherein material of said insulating and heat-insulating means is quartz.

5. The apparatus for plasma processing according to claim 2, wherein said electrode comprises electrode plates of two layers inside itself.

6. The apparatus for plasma processing according to claim 3, wherein material of said insulating and heat-insulating means is quartz.

7. The apparatus for plasma processing according to claim 1, wherein said electrode comprises electrode plates of two layers inside itself.

8. The apparatus for plasma processing according to claim 2, wherein said electrode comprises electrode plates of two layers inside itself.

9. The apparatus for plasma processing according to claim 3, wherein said electrode comprises electrode plates of two layers inside itself.

10. The apparatus for plasma processing according to claim 4, wherein said electrode comprises electrode plates of two layers inside itself.
